(19) United States
(12) Patent Application Publication
(10) Pub. No.: US 2025/0133810 A1
(43) Pub. Date: Apr. 24, 2025

(54) Method for producing a bottom oxide

(71) Applicant: Fraunhofer-Gesellschaft zur Förderung der angewandten Forschung e.V., München (DE)

(72) Inventors: Minwho LIM, Erlangen (DE); Alesa FUCHS, Erlangen (DE); Tobias ERLBACHER, Erlangen (DE)

(73) Assignee: Fraunhofer-Gesellschaft zur Förderung der angewandten Forschung e.V., München (DE)

(21) Appl. No.: 18/925,055

(22) Filed: Oct. 24, 2024

(30) Foreign Application Priority Data
Oct. 24, 2023 (DE) 102023210487.3

(51) Int. Cl. H01L 29/51; H01L 21/04; H01L 21/28; H01L 27/088; H01L 29/16; H01L 29/423; H01L 29/66

(52) U.S. Cl. CPC H10D 64/691; H01L 21/049; H01L 21/28211; H10D 12/031; H10D 62/8325; H10D 64/015; H10D 64/513; H10D 84/83

(57) ABSTRACT

A method for producing a (thick) bottom oxide in a trench structure, having the following steps: providing a substrate having at least one trench structure comprising a bottom and sidewalls; depositing a polysilicon layer on a surface of the substrate, the bottom and the sidewalls; depositing an oxide layer on the polysilicon layer; depositing a nitride layer on the oxide layer; anisotropic dry etching of the nitride layer; thermal oxidation of the polysilicon of the polysilicon layer to produce a thick oxide layer locally; and wet etching; depositing a further oxide layer on the thick oxide layer along at least the bottom and the surface or on the residual oxide along the bottom and the surface and on the sidewalls.

### CROSS-REFERENCE TO RELATED APPLICATION

This application claims priority from German Patent Application No. 102023210487.3, which was filed on Oct. 24, 2023, and is incorporated herein by reference in its entirety.

### TECHNICAL FIELD

Embodiments of the present invention relate to a method for producing a (thick) bottom oxide. Further embodiments relate to a resulting product. In general, embodiments of the present invention are in the field of MOSFET transistors or trench MOSFET transistors. Preferred embodiments are concerned with the process of producing the gate oxide in a trench MOSFET (metal-oxide semiconductor field-effect transistor), a type of silicon carbide-based (SiC) power semiconductor element.

### BACKGROUND OF THE INVENTION

SiC-based trench MOSFETs have a potential for reducing an on resistance, which is primarily attributed to a higher cell density without JFET regions. Furthermore, a trench MOSFET has a possibly improved channel mobility on the trench side, in particular when compared to planar MOSFETs. This feature results in a high cell integration density, thereby reducing the chip area and ultimately decreasing unit costs.

In embodiments of the present invention, it has been recognized that the gate oxide plays an important role in determining the channel mobility along the trench sidewall. This is intensively exposed to electric fields at the trench bottom so that need for optimization has been recognized here.

In the known technology, there are some approaches for improving the properties and manufacturability of the gate oxide.

In order to solve the problem of premature breakdown of the gate oxide, different extended shielding configurations have been suggested. Among these configurations, the TBO (Thick Bottom Oxide) structure is promising. This approach includes inserting gate trenches with a thick oxide layer on the trench bottom, thereby effectively increasing the electric field strength of the gate oxide layer.

The known technology for the process of producing the TBO gate oxide in silicon (Si) is the local oxidation of silicon (LOCOS), wherein the Si is oxidized locally during the thermal oxidation of the substrate by using an oxidation-resistant mask, usually silicon nitride (Si₃N₄). After forming the TBO on the trench bottom and removing the mask, the trench sidewalls can be oxidized equally (U.S. Pat. No. 20,202,43679A1, 2020).

Due to the dependence of the direction of the plane on oxidation rates, TBO production in SiC trench structures on SiC is more difficult since the trench sidewalls comprise higher oxidation rates. One approach is using an analogous LOCOS method, wherein the trench sidewall is covered with a thin oxide layer and an Si₃N₄ mask during the thermal oxidation of the SiC substrate such that only trench bottom and mesa are oxidized. After removing the mask via wet etching, the thin oxide layer remains on the trench sidewall whereas a thick oxide has been formed on mesa and bottom of the trench, which can be oxidized again to form the gate oxide (U.S. Pat. No. 5,915,180A, 1990). Here, the difference between the thickness of the bottom oxide and the sidewall oxide is limited depending on the intended thickness of the sidewall oxide due to the higher oxidation rate.

Another approach for forming the TBO in the gate trenches is filling the trenches by oxide deposition followed by an etch back process such that the SiC mesa is exposed. After that, the gate oxide can be formed by thermal oxidation or a CVD process (U.S. Pat. No. 20,183,66569A1, 2018). In this approach, in the oxide etch back process, the selectivity must be sufficient to prevent etching into the SiC substrate.

As shown above, the known technology has some disadvantages, wherein recognizing these disadvantages already forms part of the subject-matter of the invention.

Starting from disadvantages recognized, it is an object underlying the present invention to provide a concept for producing a bottom oxide, in particular for semiconductor devices such as MOSFETs or trench MOSFETs, offering an improved compromise between produced quality and manufacturability.

### SUMMARY

According to an embodiment, a method for producing a (thick) bottom oxide in a trench structure may have the steps of: providing a substrate with at least one trench structure comprising a bottom and sidewalls; depositing a polysilicon layer on a surface of the substrate, the bottom and the sidewalls; depositing an oxide layer on the polysilicon layer; depositing a nitride layer on the oxide layer; anisotropic dry etching of the nitride layer; thermal oxidation of the polysilicon of the polysilicon layer to produce a thick oxide layer locally; wet etching; depositing a further oxide layer on the thick oxide layer along at least the bottom and the surface or on the thick oxide layer along the bottom and the surface and on the sidewalls.

Another embodiment may have a semiconductor device, in particular a MOSFET or trench MOSFET with a thick oxide produced by a method for producing as mentioned above.

Still another embodiment may have a semiconductor device, in particular a MOSFET or trench MOSFET with a thick oxide, wherein the semiconductor device has an SiC substrate with one or more trenches and an oxidized polysilicon at a bottom of the one or more trenches and the surface of the substrate.

Embodiments of the present invention provide a method for producing a (thick) bottom oxide in a trench structure, e.g. a trench structure of a semiconductor substrate. The method comprises the steps of:
providing a substrate with at least one trench structure or more trenches, wherein at least one trench structure comprises a bottom and sidewalls;
depositing a polysilicon layer on a surface of the substrate, the bottom and the sidewalls;
depositing an oxide layer, e.g. a silicon dioxide layer, on the polysilicon layer, i.e. for example along the bottom and the sidewalls;

depositing a nitride layer, such as a silicon nitride (Si₃N₄), on the oxide layer, i.e. for example again along the bottom and the sidewalls;
anisotropic dry etching of the nitride layer;
triggering a thermal oxidation of the polysilicon and the polysilicon layer to produce a thick oxide layer locally;
isotropic wet etching of the nitride layer, the oxide layer and the polysilicon of the sidewalls, e.g. in the trench structure;
depositing a further oxide layer on the residual oxide along at least the bottom and the surface or on the residual oxide along the bottom and the surface and on the sidewalls.

According to embodiments, the substrate can be a substrate made of a silicon material, such as e.g. silicon carbide (SiC).

Embodiments of the present invention are based on the finding that a so-called spacer is formed along the sidewalls by the selected order of depositing polysilicon, oxide and nitride in combination with dry etching through the nitride of the nitride layer according to embodiments. In the subsequent oxidation step, this spacer prevents the polysilicon from oxidizing along the sidewalls. Thus, oxidation on the surface of the substrate and on the bottom of the substrate is promoted, which results in a thick bottom oxide forming, e.g. with an elevation. In the subsequent isotropic etching (wet etching) in the trench structure, the oxide layer is also etched back, but above all exposure of the sidewalls is achieved such that in the last basic step of depositing a further oxide layer a thin oxide layer forms on the sidewalls and a thick oxide layer (resulting thick oxide layer) forms on the bottom. This is a self-aligned process.

The suggested solution is based on simplifying the lithography aspects of the TBO (Thick Bottom Oxide) structure by implementing a self-aligned process which uses the LOCOS technique. Using this self-aligned approach, the TBO structure can be developed without being limited by restrictions with respect to the lithographic resolution and the adjustment accuracy. The use of the self-aligned process serves as a compensating measure for the increased technological complexity used to produce a stable TBO structure.

According to embodiments, during dry etching the nitride of the nitride layer on the bottom and the surface is removed such that for example during dry etching the oxide of the oxide layer on the bottom and the surface is exposed. Due to the anisotropy of the dry etching process, a spacer made of nitride of the nitride layer is formed along the sidewalls by the nitride remaining there and not being etched. According to embodiments, this nitride or the spacer protects the exposed oxide and the underlying polysilicon from oxidation in the subsequent oxidation process. According to embodiments, oxidation takes place at the exposed bottom and the exposed surface. This means that according to further embodiments no oxidation takes place along the sidewalls and/or in the region of the spacer made of nitride of the nitride layer along the sidewalls. For example, oxidation can be triggered at a temperature which allows oxidation of the polysilicon without causing oxidation of the material of the substrate, such as e.g. the silicon carbide. According to embodiments, during oxidation, the polysilicon can bond with the oxide to thus form a thick oxide region at the bottom and/or at the surface.

In the subsequent isotropic etching (wet etching), the spacer made of nitride is removed along the sidewall. According to embodiments, a part of the oxide layer and/or the polysilicon layer, e.g. which were previously covered by the nitride layer of the spacer, can also be removed. According to embodiments, etching back of the oxide layer at the bottom and/or the surface can also take place. According to embodiments, the wet etching is characterized by high selectivity for polysilicon and/or nitride. According to embodiments, the wet etching can also be performed such that a buffered etching process is used to remove the oxide along the sidewall. According to embodiments, the wet etching process takes place in several wet etching steps.

An additional advantage results from producing the gate oxide layer on the trench sidewalls, which does not depend on whether the oxide is deposited or grown thermally. In the context of other common manufacturing processes for the TBO structure, the application of thermal oxide can be challenging due to the significant thickness of the oxide layer only at the trench bottom. When thermal oxidation is used, a very thin oxide layer is produced on the SiC mesa, while at the same time attempting to achieve the desired thickness of the oxide on the trench sidewalls. This is because the oxidation rate of the SiC trench sidewalls is significantly higher when compared to the SiC mesa. By using a self-aligned process for producing a thick oxide layer on the trench bottom and SiC mesa, providing an oxide layer with the desired properties by deposition or thermal oxidation can be realized.

According to embodiments, LPCVD technology can be used for depositing the oxide layer and/or for depositing the nitride layer. This is of advantage because the sidewall in the trench structure is also coated equally in this way.

According to embodiments, the method can be extended in that after the further oxide layer has been applied, which according to embodiments can again be done by means of LPCVD, a gate is also introduced in the trench structure, i.e. the trench structure with the thick bottom oxide.

Further embodiments relate to a semiconductor device, in particular a MOSFET or trench MOSFET with a thick oxide produced by a method as explained above. According to an embodiment, the semiconductor device comprises an SiC substrate with one or more trenches and an oxidized polysilicon at a bottom of the one or more trenches (14) and the surface (120) of the substrate (12). The semiconductor device can comprise one or more trench MOSFETs arranged in the one or more trenches.

### BRIEF DESCRIPTION OF THE DRAWINGS

Embodiments of the present invention will be explained below referring to the appended drawings, in which:

FIG. 1 shows a schematic flow diagram of a basic method for producing a (deep) trench according to embodiments;

FIGS. 2a-d show schematic representations of individual process steps for producing a semiconductor device with a trench structure according to embodiments; and

FIGS. 3a-c show representations of intermediate products in the production of semiconductor device according to embodiments.

### DETAILED DESCRIPTION OF THE INVENTION

Before embodiments of the present invention will be explained below referring to the appended drawings, it is to be pointed out that equal components and structures are provided with equal reference numerals so that the description thereof is mutually applicable or interchangeable.

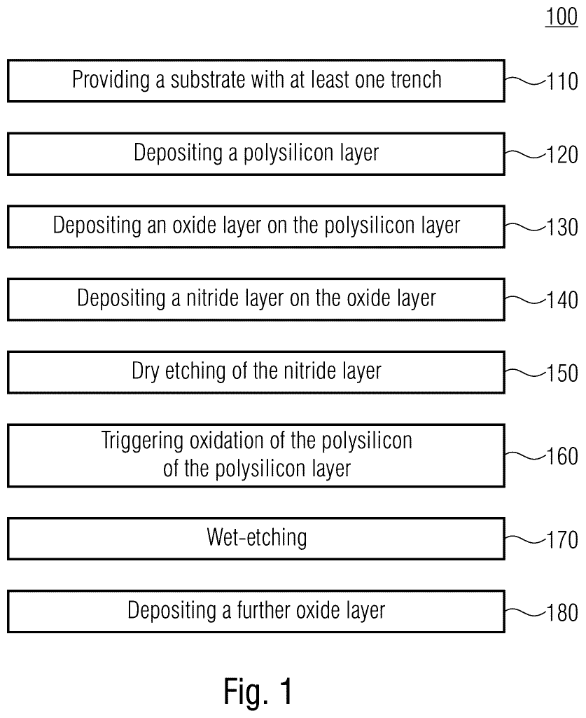

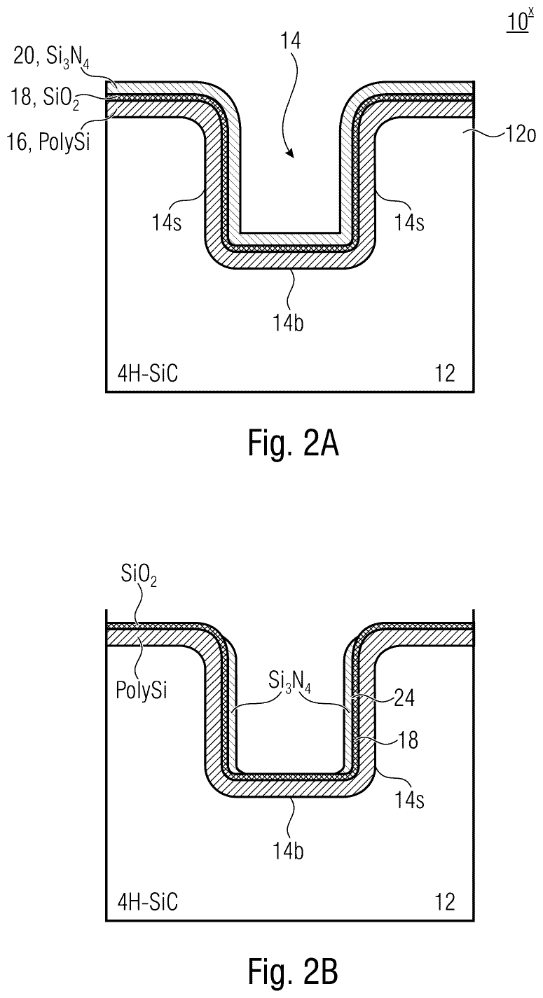

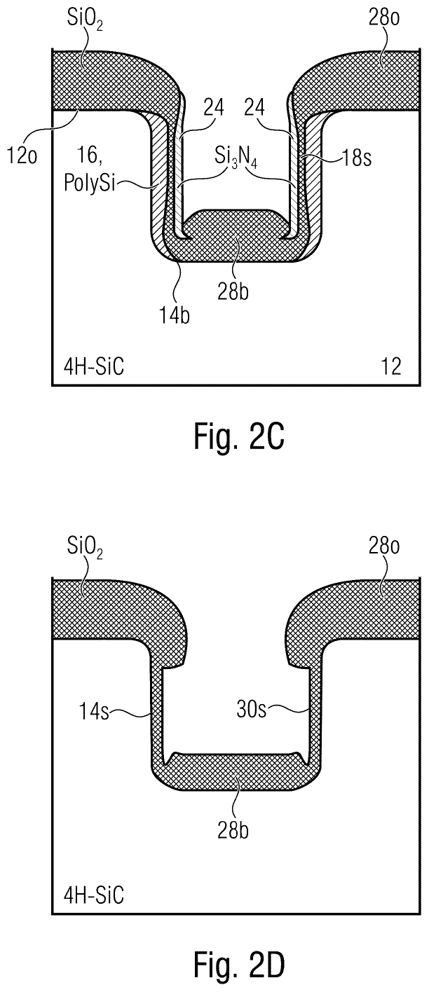

FIG. 1 shows a method 100 for producing a semiconductor device 10 as shown in FIGS. 2a-d and 3a-c. The method 100 illustrates the basic steps, wherein optional steps are shown with dashed blocks in the flow diagram.

In the initial step, a substrate 12 with at least one trench structure is provided, but advantageously more trenches 14. This step is marked with the reference numeral 110. In this step 110, optional steps of processing the substrate 10, e.g. by etching the trenches 14 or by growing an SiC layer 12s, may have preceded. These steps are not shown.

As can be seen in FIG. 2a, the substrate 12 comprises at least one trench structure 14 having sidewalls 14s and a bottom 14b. The surface of the substrate is marked with the reference numeral 120. The polysilicon layer 16 is deposited on the surface 120, the sidewalls 14s and the bottom 14b. This step is provided with the reference numeral 120 in the diagram of FIG. 1. According to embodiments, depositing can take place by means of LPCVD. After this step, the step of depositing an oxide layer 18 on the polysilicon layer 16 takes place. This step is provided with the reference numeral 130. In the subsequent step, a nitride layer 20 is deposited on the oxide layer 18. As can be seen with reference to FIG. 2a, both depositing the oxide layer 18, for example silicon dioxide (SiO₂), and/or also depositing the nitride layer 20, such as silicon nitride (Si₃N₄), take place such that the sheets extend along the surface 120, sidewall 14s and bottom 14b. According to embodiments, this may also be referred to as a full-surface deposition in at least the local region of the trench 14. After step 140 of depositing the nitride layer 20, individual regions are opened again. This takes place by means of dry etching in step 150. Due to the dry etching, the nitride layer 20 is removed in the region of the bottom 14b and also the surface 120, wherein the nitride or silicon nitride of the sheet 20 remains along the sidewall 14s. This so-called spacer is provided with the reference numeral 24. The spacer 24 covers the oxide layer 18 and polysilicon layer 16 along the sidewall 14s.

In the subsequent step, oxidation takes place. This is triggered, for example, by a corresponding temperature. During oxidation, the polysilicon 16 of the polysilicon layer oxidizes. The step is provided with the reference numeral 160 and is illustrated in FIG. 2c. By oxidation, the silicon dioxide is formed in the region of the surface 120 and on the bottom 14b so that a thick oxide bottom 28b and a corresponding surface 280 are formed. The bottom 28b may comprise an elevation in the region of the spacers 24. By means of the spacers 24, no oxidation of the polysilicon 16 along the sidewall 14s takes place and no connection to the oxide 18 along the sidewall 14s.

In subsequent step 170, at least the spacer 24, but, according to embodiments, also the polysilicon 16 and the oxide 18 in the region of the sidewall 14s are removed. This step is marked with the reference numeral 170 in the flow diagram and may have several sub-steps of wet etching. Especially the nitride of the spacer 24 and the polysilicon 16 can be easily removed due to the high selectivity, while the wet chemical removal of the oxide 18 between the elements 16 and 24 in the region of the sidewall 14s is based on precise control of the wet etching process. For example, a BOE (Buffered Oxide Etching) process can be used. During wet etching 170, parts of the regions 280 and 28b can also be removed, for example the surface of the regions 280 and 28b is removed. Due to the previous oxidation in step 160, however, the regions 280 and 28b are thickened such that a residual oxide remains.

Starting from this prerequisite, a further oxide layer can then be produced in step 180. This takes place for example by means of LPCVD such that the sidewalls 14s exposed in the previous step are coated again with an oxide. As a result, the oxide layer is thickened in the region 280 and 28b while these have a reduced layer thickness along the sidewall 14s. The result is shown in FIG. 2d. The layer produced by LPCVD along the sidewalls 14s is also called TEOS layer.

The method for producing a TBO (Thick Bottom Oxide) structure will be explained below referring to FIGS. 2a to 2d. FIGS. 2a-2d illustrate a semiconductor device as an intermediate product which is marked as 10* in steps 2a to 2c and as a final intermediate product 10 in FIG. 2d. As already noted, after the state 10 of FIG. 2d, further processing with one or more steps can also take place.

The semiconductor device 10* or 10 comprises one or more trench structures 14 introduced into a substrate 12. The substrate 12 is, for example, a silicon substrate or, in particular, a silicon carbide (SiC) substrate so that SiC trench MOSFETs can be produced by means of this production method. Due to the method steps, in particular depositing the spacer 24 and subsequent wet etching, the resulting wall regions 30s (cf. FIG. 2d) and also the thick bottom regions 28b and thick surface regions 280 are self-aligned. In this respect, this is a self-aligned process which comprises the LOCOS technique (LOCOS=Local Oxidation of Silicon). The LOCOS process is usually used for isolation in CMOS production in order to produce individual regions on a silicon substrate.

FIGS. 2a-d illustrate the process for producing the gate oxide 30s with a TBO structure 28b step by step. As shown in FIG. 2a, the process starts with the preparation of an n-type epitaxial 4H-SiC wafer 12, followed by trench structuring (cf. trench structure 14). At first, a layer of polysilicon 16 is deposited and then a thin oxide layer 18 is added. A thin layer 20 made of silicon nitride (Si₃N₄) is then deposited using the LPCVD technique. The thin oxide layer 18 serves as an indicator for endpoint detection during dry etching (cf. 150) of the nitride layer 20. The nitride layer 20 is etched anisotropically, for example, in order to form the spacer 24 illustrated in FIG. 2b. In the subsequent step (FIG. 2c), the polysilicon 16 is subjected to oxidation (cf. 160) at a specific temperature which is selected in order to facilitate oxidation of the polysilicon 16 and at the same time avoid the oxidation of SiC 12. The regions made of polysilicon which are exposed and not covered by the nitride mask 24 undergo oxidation 160, similar to the process used in LOCOS. This results in the formation of a thick thermal oxide layer 28b and 280 on mesa and trench bottom. The polysilicon at the trench sidewalls 14s remains laterally non-oxidized due to the presence of the nitride mask 24 which acts as a barrier. Finally, the layers at the trench sidewalls 24s, including the nitride (spacer) layer 24, the TEOS layer 18s and the polysilicon layer 16, are removed completely, leaving an empty space at the trench sidewalls 14s. Since the trench geometry of the trench 14 is not suitable for anisotropic dry etching, an isotropic etching technique (cf. 170) is used to remove the materials at the trench sidewalls 14s. The removal process 170 comprises several steps of wet etching in order to remove the layers of Si₃N₄ 24, SiO₂ 18s and polysilicon 16. The main challenge is etching SiO₂ 18s at the trench sidewalls 14s. While over-etching of Si₃N₄ 24 and polysilicon 16 is permissible substantially due to its high selectivity, etching the oxide layer 18 entails careful control in order to prevent undesired excessive removal of the oxide layer on mesa and trench bottom. A careful approach is used when the BOE (Buffered Oxide Etching) process is used to remove the thin TEOS layer which is assumed to be present between the spacer and the polysilicon layers at the trench sidewalls. After complete removal of the layers at the trench sidewalls, the TEOS layer is deposited to produce the gate oxide using the LPCVD technique (cf. FIG. 2d).

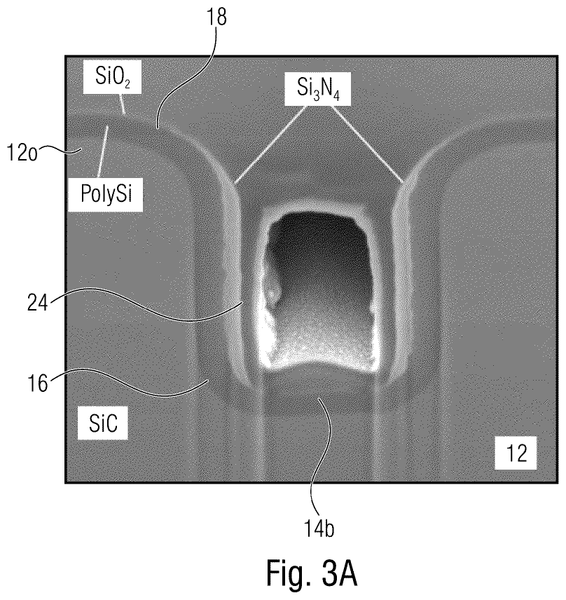

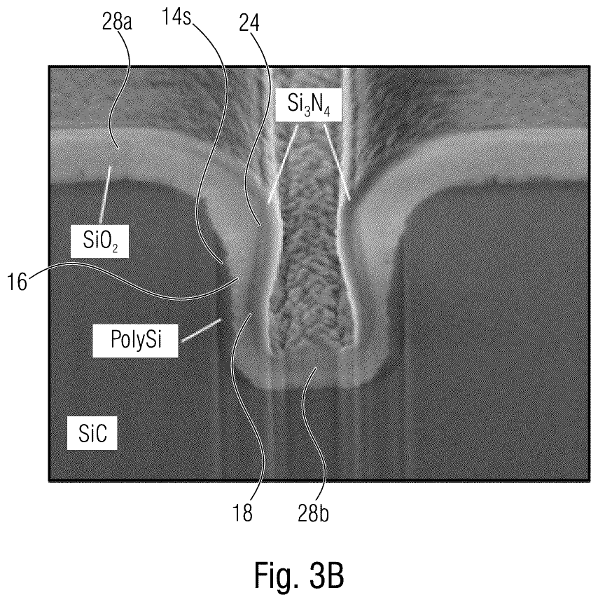

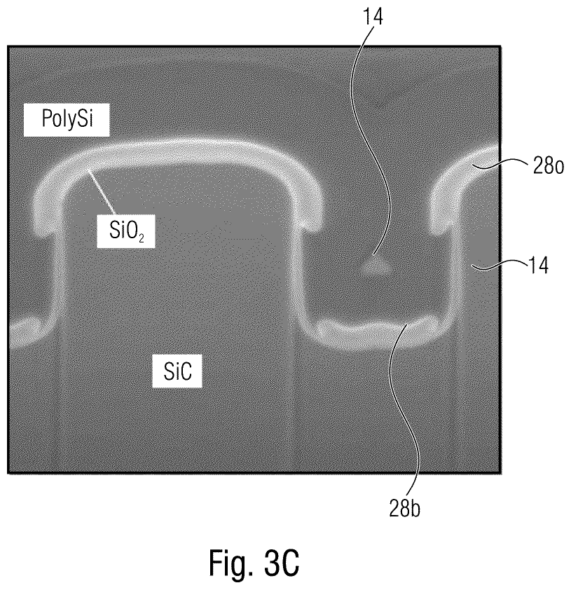

FIGS. 3a, 3b and 3c show the steps of forming the spacer by dry etching 150, triggering an oxidation according to step 160, and forming a thick oxide after the deposition 180 by means of microscopy images, here images for cross-sectional analysis using a focused ion beam (FIB). FIG. 3a shows the spacer 24 together with the polysilicon 16 at the bottom and the surface 120. Here, a remainder of the oxide layer 18 is also shown. FIG. 3b then shows oxidation in the region of the surface 120 (cf. reference numeral 280) and at the bottom (cf. reference numeral 28b). As can be seen, polysilicon 16 remains in the region of the sidewall 14s even after oxidation.

FIG. 3c then shows the state after removing the spacer 24, the polysilicon 16 and the oxide 18 along the trench sidewall 14s. As can be seen, the oxide region 280 and 28b remains in the trench 14. It can also be seen in the representation that several trenches can be produced next to one another at the same time. The state shown in FIG. 2d or 3c represents an intermediate product, starting from which further steps for producing the SiC trench MOSFET may follow. For example, in a subsequent step, a gate region can be formed in the trench 14. The source or drain region is then optionally formed on the surface after further isotropic or anisotropic etching processes or thinning processes.

Even if embodiments of the present invention are explained in particular referring to a production method, a further embodiment relates to a product produced with the corresponding production method, such as a trench MOSFET. A semiconductor product produced in this way is characterized in that it has a thick bottom oxide and, in particular, the oxide regions are formed uniformly with reduced thickness along the sidewall 14s of the gate oxide. The background here is the self-aligned process by using the spacer and the corresponding oxidation and wet etching processes. Thus, it is of advantage with the product that the process parameters, in particular the thickness/dimensioning of the gate oxide, can be controlled optimally here. The quality of the oxide differs from existing products. Here, polysilicon is oxidized (not the SiC) and, in addition, both thermal oxidation and deposition/LPCVD can be applied in principle in the last oxidation step (producing the gate oxide). According to embodiments, the semiconductor product comprises SiC as a substrate and oxidized polysilicon at the bottom 14b and mesa/surface 120.

Even if embodiments of the present invention were explained referring to the production method, it is to be pointed out that the explanation of the corresponding method step is equivalent to an explanation of the corresponding feature. Conversely, it is to be understood that these aspects also represent a description of the corresponding method so that a block or a component of a device is also to be understood to be a corresponding method step or feature of a method step. In analogy, aspects described in connection with or as a method step also represent a description of a corresponding block or detail or feature of a corresponding device.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A method for producing a (thick) bottom oxide in a trench structure, comprising:
providing a substrate with at least one trench structure comprising a bottom and sidewalls;
depositing a polysilicon layer on a surface of the substrate, the bottom and the sidewalls;
depositing an oxide layer on the polysilicon layer;
depositing a nitride layer on the oxide layer;
anisotropic dry etching of the nitride layer;
thermal oxidation of the polysilicon of the polysilicon layer to produce a thick oxide layer locally;
wet etching;
depositing a further oxide layer on the thick oxide layer along at least the bottom and the surface or on the thick oxide layer along the bottom and the surface and on the sidewalls.

2. The method for producing according to claim 1, wherein a spacer made of nitride of the nitride layer remains and/or is formed along the sidewalls during dry etching.

3. The method according to claim 1, wherein nitride of the nitride layer on the bottom and the surface is removed during dry etching and/or wherein the oxide of the oxide layer on the bottom and the surface is exposed during dry etching.

4. The method according to claim 1, wherein oxidation of the bottom exposed by the nitride and of the exposed surface takes place during oxidation.

5. The method according to claim 1, wherein no oxidation takes place along the sidewall and/or in the region of a spacer made of nitride of the nitride layer along the sidewall during oxidation.

6. The method according to claim 1, wherein the polysilicon bonds with the oxide during oxidation to form a thick oxide region at the bottom and/or at the surface; and/or wherein triggering the oxidation takes place at a temperature which also allows oxidation of the polysilicon without causing oxidation of a material of the substrate.

7. The method according to claim 1, wherein a spacer made of nitride of the nitride layer is removed along the sidewall during wet etching; and/or wherein a part of the oxide layer and/or a part of the polysilicon layer are removed during wet etching.

8. The method according to claim 1, wherein wet etching takes place with high selectivity; and/or wherein a buffered etching process is performed during wet etching to remove the oxide along the sidewall; and/or wherein wet etching comprises several wet etching processes.

9. The method according to claim 1, wherein depositing the further oxide layer and/or depositing the nitride layer take place by means of LPCVD technology.

10. The method according to claim 1, wherein the oxide comprises a silicon dioxide and/or SiO₂.

11. The method according to claim 1, wherein the substrate comprises a silicon material and/or a silicon carbide material and/or an SiC.

12. The method according to claim 1, wherein the nitride comprises a silicon nitride and/or an Si₃N₄.

13. The method according to claim 1, wherein the method comprises forming a gate in the trench structure with the bottom oxide.

14. A semiconductor device, in particular a MOSFET or trench MOSFET with a thick oxide produced by a method according to claim 1.

15. A semiconductor device, in particular a MOSFET or trench MOSFET with a thick oxide, wherein the semiconductor device comprises an SiC substrate with one or more trenches and an oxidized polysilicon at a bottom of the one or more trenches and the surface of the substrate.

16. The semiconductor device according to claim 14, comprising one or more trench MOSFETs arranged in the one or more trenches.

17. The semiconductor device according to claim 15, comprising one or more trench MOSFETs arranged in the one or more trenches.
